(19) United States
(12) Patent Application Publication
(10) Pub. No.: US 2006/0121731 A1
(43) Pub. Date: Jun. 8, 2006

(54) Semiconductor manufacturing system and method for manufacturing a semiconductor device

(76) Inventor: Takashi Suzuki, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/290,428

(22) Filed: Dec. 1, 2005

(30) Foreign Application Priority Data
Dec. 2, 2004 (JP) P2004-349711

(51) Int. Cl. B05C 11/02; H01L 21/44

(52) U.S. Cl. 438/660; 118/117

(57) ABSTRACT

A semiconductor manufacturing system, includes: a reaction tube housing a target object; a plurality of material gas introduction pipes, connected to an upstream side of the reaction tube, introducing a first material gas containing a compound of silicon, and a second material gas containing at least one of nitrogen gas and a compound of nitrogen, in the reaction tube; and a suppression gas introduction pipe, connected to an upstream side of the reaction tube, introducing a suppression gas to suppress generation of a reaction subproduct generated by a reaction between the first and second material gases.

### CROSS REFERENCE TO RELATED APPLICATIONS AND INCOORPORATED BY REFERRENCE

The application is based upon and claims the benefit of priority from the prior Japanese Patent Applications No. P2004-349711, filed on Dec. 2, 2004; the entire contents of which are incorporated herein by reference.

### BACKGROUND OF THE INVENTION

1. Field of the Invention

The present invention relates to a semiconductor manufacturing system, more particularly, to a semiconductor manufacturing system for depositing a thin film on a target object and a method for manufacturing a semiconductor device thereby.

2. Description of the Related Art

A vertical low pressure chemical vapor deposition (LPCVD) system is known as a semiconductor manufacturing system for forming a thin film on a target object. In the vertical LPCVD system, material gas containing a constituent element of the thin film is introduced into a lower portion (upstream side) of a reaction tube, and a thin film is deposited on a target object (semiconductor substrate) provided in an upper portion (downstream side) of the reaction tube. In this case, in the reaction tube, a subproduct is generated by reaction of the material gas together with a main product serving as the constituent element of the thin film. Particles of the subproduct adhere onto the semiconductor substrate. As a result, yield in manufacturing a semiconductor device decreases.

As a method for suppressing occurrence of the particles when forming the thin film on the target object, a method has been proposed of heating the lower portion (upstream side) of the reaction tube in order to prevent formation of particles from the subproduct from adhering onto an inner wall of the lower portion (upstream side) of the reaction tube. However, a seal member, such as an O-ring, is sometimes fused due to the heating. Therefore the above-described problem has not been solved yet.

### SUMMARY OF THE INVENTION

An aspect of the present invention inheres in a semiconductor manufacturing system adapted for depositing a thin film on a target object, including: a reaction tube configured to house the target object; a plurality of material gas introduction pipes, connected to an upstream side of the reaction tube, configured to introduce a first material gas containing a compound of silicon, and a second material gas containing at least one of nitrogen gas and a compound of nitrogen, in the reaction tube, respectively and independently of each other; and a suppression gas introduction pipe, connected to an upstream side of the reaction tube, configured to introduce a suppression gas to suppress generation of a reaction subproduct generated by a reaction between the first and second material gases.

Another aspect of the present invention inheres in a method for manufacturing a semiconductor device, including: heating a semiconductor substrate in a reaction tube to a growth temperature; maintaining the growth temperature; introducing a first material gas containing a compound of silicon, and a second material gas containing at least one of nitrogen gas and a compound of nitrogen from an upstream side of the reaction tube, respectively and independently of each other so as to deposit a thin film on the semiconductor substrate from a reaction between the first and the second material gases; and introducing a suppression gas, to suppress generation of a reaction subproduct generated by the reaction, from the upstream side of the reaction tube.

### BRIEF DESCRIPTION OF DRAWINGS

FIG. 1 is a schematic cross-sectional view showing an example of a semiconductor manufacturing system according to an embodiment of the present invention.

FIG. 2 is a schematic cross-sectional view of the semiconductor manufacturing system of FIG. 1, cutting a lower portion of a reaction tube of the semiconductor manufacturing system by a horizontal plane so that FIG. 1 represents the schematic cross-sectional taken on line I-I in FIG. 2.

FIG. 3 is a flowchart for explaining an example of a method for manufacturing a semiconductor device according to the embodiment of the present invention.

### DETAILED DESCRIPTION OF THE INVENTION

An embodiment and various modifications of the present invention will be described with reference to the accompanying drawings. It is to be noted that the same or similar reference numerals are applied to the same or similar parts and elements throughout the drawings, and the description of the same or similar parts and elements will be omitted or simplified.

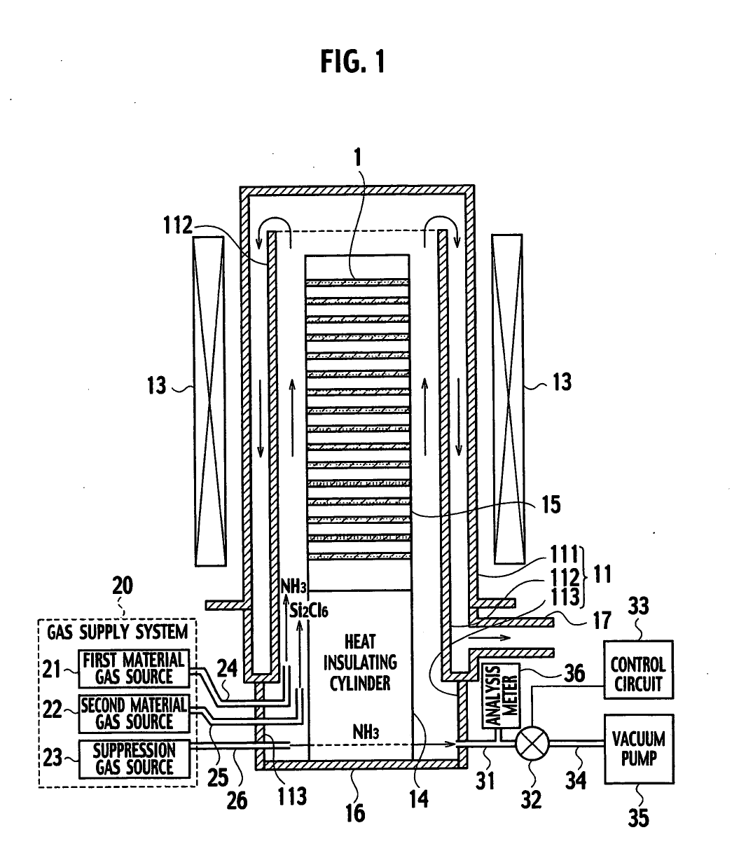

As shown in FIG. 1, a semiconductor manufacturing system according to this embodiment of the present invention is a vertical LPCVD system, which is adapted for depositing a thin film on a target object 1, including a reaction tube 11 which houses the target object 1, a plurality (first and second) of material gas introduction pipes 24 and 25 connected to an upstream side of the reaction tube 11 to introduce, onto the target object 1, a first material gas having a compound containing silicon (Si) and a second material gas having at least one of nitrogen (N) gas and a compound containing N, respectively, and independently of each other, and a suppression gas introduction pipe 26 which is connected to the upstream side of the reaction tube 11 and introduces a suppression gas to suppress generation of a reaction subproduct from a reaction of the first and second material gases.

The reaction tube 11 is a vertical reaction tube having a hermetically sealed structure capable of shutting off the outside air and maintaining the atmosphere the inside the reaction tube 11. The reaction tube 11 includes a cylindrical outer tube 111 having a vertical tube axis, a cylindrical inner tube 112 disposed inside of the outer tube 111, and a manifold 113 disposed under the outer tube 111. The outer tube 111 is made of quartz or the like, the inner tube 112 is made of quarts or the like, and the manifold 113 is made of stainless steel or the like.

Here, though the “upstream side” and the “downstream side” are not strictly defined, for example, the “upstream side” is defined as a low-temperature side at a temperature of approximately 200° C. in the vicinity of the reaction tube 11, which is surrounded by the manifold 113. The “downstream side” is defined as a high-temperature side at a temperature of approximately 400 to 600° C. in the vicinity surrounded by the inner tube 112. On the outside of the outer tube 111, a heating furnace (heater) 13 is provided to control the temperature in the reaction tube 11.

Disposed inside of the inner tube 112 is a susceptor 15 made of quartz or the like, which mounts the target object 1 thereon. For example, a semiconductor substrate (semiconductor wafer) is the target object 1. Usually, with regard to the target object 1, it is possible to put 100 to 150 such targets into the susceptor 15. Provided under the susceptor 15 is a heat insulating cylinder 14 made of quartz or the like for insulating a lower portion of the reaction tube 11 from heat. An outlet pipe 17 is provided in the outer tube 111. The outlet pipe 17 is connected to a vacuum pump (not shown), and maintains the inside of the reaction tube 11 at a reduced pressure (low pressure) state of, for example, approximately 20 to 200 Pa.

One end of each of the material gas introduction pipes 24 and 25, the suppression gas introduction pipe 26, and an exhaust pipe 31 is connected to the manifold 113. A gas supply system 20 is connected to the other ends of the material gas introduction pipes 24 and 25 and the suppression gas introduction pipe 26. The gas supply system 20 includes a first material gas source 21 connected to the material gas introduction pipe 24, a second material gas source 22 connected to the material gas introduction pipe 25, and a suppression gas source 23 connected to the suppression gas introduction pipe 26.

For example, in the case of depositing a silicon nitride film (Si₃N₄ film), the first material gas source 21 supplies, for example, silicon hexachloride (Si₂Cl₆) gas as the first material gas. The second material gas source 22 supplies ammonia (NH₃) gas as the second material gas. The suppression gas source 23 supplies, for example, NH₃ gas as the suppression gas.

The material gas introduction pipes 24 and 25 are injector nozzles which introduce the NH₃ gas and the Si₂Cl₆ gas in the vertical direction, respectively, so as to flow the above-described NH₃ gas and Si₂Cl₆ gas from the upstream side of the reaction tube 11 to the downstream side thereof. The suppression gas introduction pipe 26 is an injector nozzle which introduces the NH₃ gas in a direction different from the direction in which the material gas introduction pipes 24 and 25 introduce the NH₃ gas and the Si₂Cl₆ gas, for example, in the horizontal direction, so that the NH₃ gas flows to the upstream side of the reaction tube 11. With regard to gas flow rates in the reaction tube 11, the flow rate of the NH₃ gas introduced through the material gas introduction pipe 24 is approximately 100 to 1000 sccm. The flow rate of the Si₂Cl₆ gas introduced through the material gas introduction pipe 25 is approximately 5 to 100 sccm. The flow rate of the NH₃ gas introduced through the suppression gas introduction pipe 26 is approximately 100 to 1000 sccm.

The exhaust pipe 31 is connected to the manifold 113 at a position opposite to the suppression gas introduction pipe 26. A vacuum pump 35 is connected to the exhaust pipe 31 through an exhaust pressure adjustment tool 32 and an exhaust pipe 34. The exhaust pipe 31 discharges the NH₃ gas introduced through the suppression gas introduction pipe 26, the subproduct generated by the reaction of the first and second material gases, and the like. The exhaust pressure adjustment tool 32 adjusts the exhaust pressure of the exhaust pipe 31. A valve and the like may be used as the exhaust pressure adjustment tool 32. An analysis meter 36 is connected to the exhaust pipe 31. The analysis meter 36 analyzes the composition and density of the gas exhausted from the exhaust pipe 31.

A control circuit 33 is connected to the exhaust pressure adjustment tool 32 and the analysis meter 36. The control circuit 33 monitors the exhaust pressure and gas flow rate of the exhaust pipe 31, and controls the exhaust pressure adjustment tool 32. The control circuit 33 controls the supply of the suppression gas from the suppression gas source 23, based on a result of the analysis by the analysis meter 36, thereby controlling an amount of the gas introduced from the suppression gas introduction pipe 26 into the reaction tube 11. A cap 16 which closes a door portion through which the target objects 1 and the susceptor 15 are delivered is provided on a lower portion of the manifold 113.

Next, an example of a reaction in the case of depositing the Si₃N₄ film on each target object 1 in the semiconductor manufacturing system according to the embodiment of the present invention will be described. It is assumed that Si₂Cl₆ gas is used as the first material gas and NH₃ gas is used as the second material gas. The S1₂Cl₆ gas and the NH₃ gas react with each other on the upstream side of the reaction tube 11, and as shown in Reaction formula (1), silicon nitride (Si₃N₄) gas is produced as a main product. Simultaneously, the subproducts such as hydrogen chloride (HCl) gas and hydrogen (H₂) gas are produced.
3Si₂Cl₆+8NH₃→2Si₃N₄+18HCl+3H₂ (1)

The Si₃N₄ gas produced according to Reaction formula (1) is adsorbed onto the target object 1, and the Si₃N₄ film is deposited thereon. Moreover, the NH₃ and the HCl gas produced according to Reaction formula (1) react with each other, and as shown in Reaction formula (2), solid ammonium chloride (NH₄Cl) is produced as the subproduct.
NH₃+HCl→NH₄Cl (2)

The NH₄Cl produced according to Reaction formula (2) adheres onto an inner wall of the manifold 113. Moreover, the NH₄Cl produced according to Reaction formula (2) reacts with the first material gas Si₂Cl₆ and as shown in Reaction formula (3), subproducts such as NH₃ gas, silane trichloride (SiHCl₃) gas, and silicone tetrachloride gas are produced.
xNH₄Cl+ySi₂Cl₆→zSiHCl₃+wSiCl₄+xNH₃ (3)
Each of x, y, z, and w is an integer of 1 or more. The SiHCl₃ gas and the SiCl₄ gas, which is produced according to Reaction formula (3), reach a surface of the target object 1 disposed on the downstream side of the reaction tube 11. Moreover, the SiHCl₃ gas and the SiCl₄ gas react with the NH₃ gas and the NH₃ gas produced according to Reaction formula (3), respectively, and as shown in Reaction formulas (4) and (5), subproducts such as HCl gas and H₂ gas are produced together with the Si₃N₄ gas as the main product.
3SiHCl₃+4NH₃→Si₃N₄+9HCl+3H₂ (4)
3SiCl₄+4NH₃→Si₃N₄+12HCl (5)

The Si₃N₄ gases as the main product, which are produced according to Reaction formulas (4) and (5), are deposited on the target object 1, and the Si₃N₄ film is thus formed. The HCl gases produced according to Reaction formulas (4) and (5) react with the NH₃ gas as the second material gas and the NH₃ gas produced according to Reaction formula (3), and as shown in Reaction formula (6), NH₄Cl is produced as the subproduct.
NH₃+HCl→NH₄Cl (6)

The NH₄Cl produced according to Reaction formula (6) adheres onto the target object 1. The NH₄Cl becomes particles when the target object 1 is removed to the outside of the reaction tube 11 while the NH₄Cl is left on the surface of the target object 1.

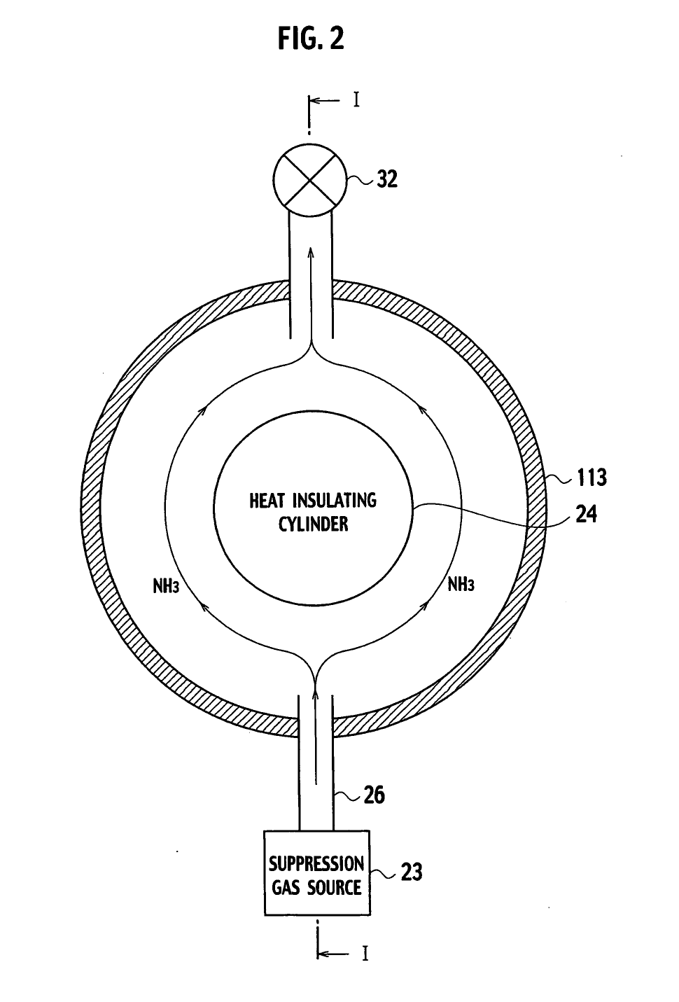

Here, in Reaction formula (3), the lower the partial pressure of the Si₂Cl₆ becomes and the higher the partial pressure of the NH₃ becomes, the reaction is more suppressed. As shown in FIG. 1 and FIG. 2, the suppression gas introduction pipe 26 blows the suppression gas supplied from the suppression gas source 23 toward the upstream side (in the horizontal direction) of the reaction tube 11. As a result, the partial pressure of the NH₃ on the upstream side of the reaction tube 11 increases, and the production reaction in Reaction formula (3) is suppressed. Hence, the production of the SiHCl₃ gas and the SiCl₄ gas, which are subproducts of the particles, is suppressed.

Next, a processing method according to the embodiment of the present invention with the semiconductor manufacturing system will be described. It is assumed, as an example, that a Si₃N₄ film is deposited on the target object 1, using Si₂Cl₆ gas as the first material gas and NH₃ gas as the second material gas.

(a) The heating furnace (heater) 13 heats the target object 1 inside of the reaction tube 11 to a growth temperature, and maintains the target object 1 at the growth temperature. For example, an area surrounded by the manifold 113 of the reaction tube 11 is maintained at a low temperature of approximately 200° C. Another area surrounded by the inner tube 112 is maintained at a high temperature of approximately 400 to 600° C. The heat insulating cylinder 14 insulates a lower position of the reaction tube 11 from the heating. The outlet pipe 17 maintains the inside of the reaction tube 11 at a reduced pressure (low pressure) state of, for example, approximately 20 to 200 Pa.

(b) The susceptor 15 with the target object 1 is arranged in the reaction tube 11. The cap 16 is fixed to the reaction tube 11. Thereby, the inside of the reaction tube 11 is in a sealed state. NH₃ gas supplied from the first material gas source 21 through the material gas introduction pipe 24 is introduced in the reaction tube 11, for example, in the vertical direction, so as to flow from the upstream side to the downstream side. Si₂Cl₆ gas supplied from the second material gas source 22 through the material gas introduction pipe 25 is introduced in the reaction tube 11 in the vertical direction, so as to flow from the upstream side to the downstream side. NH₃ gas supplied from the suppression gas source 23 through the suppression gas introduction pipe 26 is introduced in the upstream side of the reaction tube 11 in the horizontal direction.

(c) In the upstream side of the reaction tube 11, the NH₃ gas of the first material gas and the Si₂Cl₆ gas of the second material gas react with each other. As a result, as shown in Reaction formulas (1) and (2), Si₃N₄ gas is produced as the main product, and simultaneously solid NH₄Cl is produced. The solid NH₄Cl adheres to the inner wall of the manifold 113. Furthermore, by reaction of the solid NH₄Cl with the Si₂Cl₆ gas of the first material gas, as shown in Reaction formula (3), SiHCl₃ gas, SiCl₄ gas and the like are produced. Here, the suppression gas introduction pipe 26 blows NH₃ gas, as the suppression gas supplied from the suppression gas source 23, to the upstream side of the reaction tube 11 in the horizontal direction. Consequently, partial pressure of NH₃ is increased in the upstream side of the reaction tube 11, and production of the SiHCl₃ gas and the SiCl₄ gas shown in Reaction formula (3) is suppressed.

(d) In the case that SiHCl₃ gas and the SiCl₄ gas are further generated by the reaction shown in Reaction formula (3), despite suppressing generation of the SiHCl₃ gas and the SiCl₄ gas, the SiHCl₃ gas and the SiCl₄ gas are exhausted by the exhaust pipe 31. Furthermore, the NH₃ gas, which flows in the upstream side of the reaction tube 11, is exhausted from the exhaust pipe 31 so as to prevent the NH₃ gas from reaching the target object 1. Note that the control circuit 33 controls the supply of the suppression gas from the suppression gas source 23. The exhaust pressure adjustment tool 32 appropriately adjusts the exhaust pressure of the exhaust pipe 31.

According to the embodiment of the present invention, by blowing NH₃ gas from the suppression gas introduction pipe 26 to the upstream side of the reaction tube 11 in the horizontal direction, it is possible to suppress the production reaction of SiHCl₃ gas and SiCl₄ gas.

Furthermore, by providing the exhaust pipe 31 to the reaction tube 11, and by adjusting the exhaust pressure of the exhaust pipe 31 using the exhaust pressure adjustment tool 32, it is possible to exhaust SiHCl₃ gas and SiCl₄ gas to the outside of the reaction tube 11, and thereby to prevent the SiHCl₃ gas and the SiCl₄ gas contacting the target object 1. Therefore, it is possible to prevent generation of particles caused by NH₄Cl attribute to the SiHCl₃ gas and the SiCl₄ gas.

Furthermore, it is possible to also exhaust NH₃ gas flowing from the suppression gas introduction pipe 26 to the upstream side of the reaction tube 11 in the horizontal direction, without contacting the target object 1. Therefore, it is possible to prevent high density NH₃ gas on the target object 1, and to prevent deterioration of the film quality of a silicon nitride film.

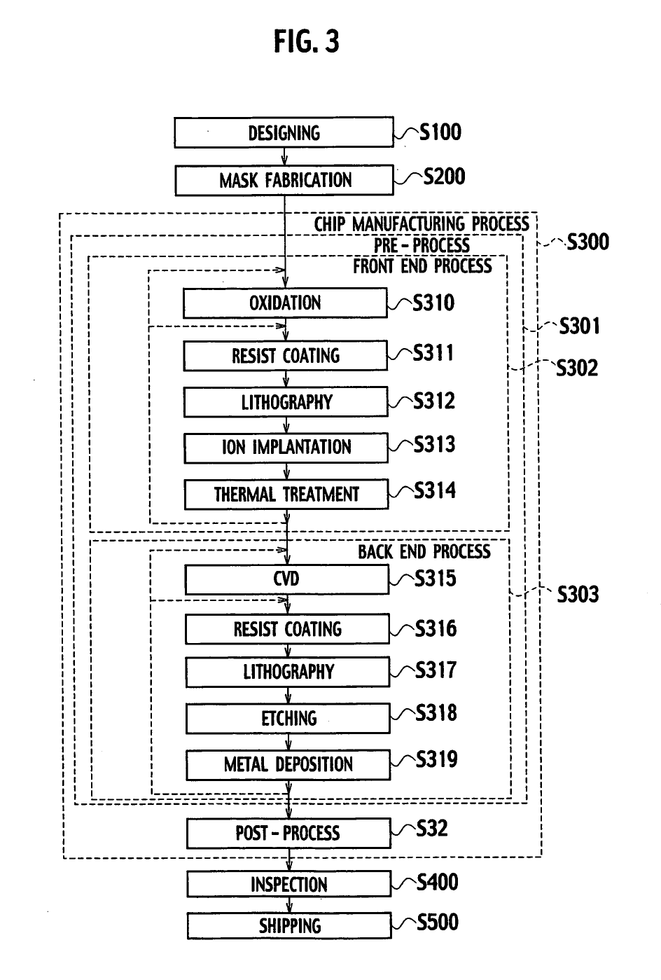

Next, a method for manufacturing a semiconductor device will be described, referring to FIG. 3. The manufacturing method described below is one example, and it is feasible to substitute modifications by various other manufacturing methods.

First, in step S100, under a given system specification, process simulation, device simulation and circuit simulation are carried out, converting the functional design prescribed by the system specification into a logical design, which is then converted into a circuit representation.

Next, in step S200, the circuit representation of various circuit components is converted into a geometric representation of patterns so as to generate a plurality of mask data corresponding to each level of mask patterns. Each level of mask patterns are delineated on a plurality of mask substrates, each level corresponds to each step of the manufacturing process of the LSI, and a set of photomasks is produced.

Next, a series of processes including such as an oxidation process in step S310, a resist coating process in step S311, the photolithography process in step S312, an ion implantation process in step S313, a thermal treatment process in step S314, and the like are repeatedly performed in a front-end process (substrate process) in step 302. In the photolithography process (step S312), the resist film coated in step S311 is delineated using a corresponding photomask in the set of photomask produced in the step S200. In the ion implantation process (step S313), the mask of the resist film delineated in the step S312 is used so as to selectively implant impurity ions into desired locations in a semiconductor wafer, through the oxide film formed on the semiconductor wafer in the step S310. The front-end process further includes various processes such as a combination of CVD process and etching process, although which are not illustrated, and the other processes are also carried out repeatedly in accordance with predetermined sequences. FIG. 3 shows one example of a part of the front-end process. For example, the thermal treatment process of step S314 may be skipped, and the resist coating process of step S311 may be carried out immediately. The front-end process may include a combination of etching process and ion implantation process after the etching process. When the above-described series of processes are completed, the procedure advances to Step S303.

Next, a back-end process (surface wiring process) for wiring the substrate surface is performed in step S303. A series of processes including a chemical vapor deposition (CVD) process of an interlevel insulator in step S315, a resist coating process for coatinig a resist film on the interlevel insulator in step S316, the photolithography process of the resist film in step S317, a selective etching process of the interlevel insulator using the delineated resist film by Step S317 as an etching mask in step S318, a metal deposition process to via holes and damascene trenches delineated in the interlevel insulator by step S318 in step 319, and the like are repeatedly performed in the back-end process. Although illustration is omitted, a metal film may be delineated by another lithography process and etching process after the deposition process of step S319. In the case of a damascene process, damascene trenches are delineated by lithography and etching after the etching process of step S318, and a metal deposition process of step S319 is carried out. Thereafter, a metal film is delineated by chemical mechanical polishing (CMP). In the step S315, using the semiconductor manufacturing system shown in FIG. 1, a thin film for the interlevel insulator is deposited on the semiconductor substrate, which is processed in the front-end process, as in the following:

The semiconductor substrate inside of the reaction tube 11 is heated to a growth temperature, and maintained at the growth temperature. A first material gas containing the compound of Si, and a second material gas, which contains at least one of N gas and a compound of N, are introduced from the upstream side of the reaction tube 11 to the semiconductor substrate, respectively, and independently of each other. Suppression gas, which suppresses generation of reaction subproducts generated by reaction of the first and second material gases, is introduced from the upstream side of the reaction tube 11. By reacting the first material gas with the second material gas, a thin film is deposited on the semiconductor substrate. When the above-described series of processes are completed, the procedure advances to Step S304.

When a multi-level interconnection structure is completed and the pre-process is finished, the substrate is diced into chips of a given size by a dicing machine such as a diamond blade in Step S304. A chip is then mounted on a packaging material made of metal, ceramic or the like. After electrode pads on the chip and leads on a leadframe are connected to one another, a desired package assembly process, such as plastic molding, is performed.

In Step S400, the semiconductor device is completed after an inspection of properties relating to performance and function of the semiconductor device, and other given inspections on lead shapes, dimensional conditions, a reliability test, and the like.

In Step S500, the semiconductor device, which has cleared the above-described processes, is packaged to be protected against moisture, static electricity and the like, and is then shipped out.

According to the method for manufacturing a semiconductor device pertaining to the embodiment of the present invention, in the CVD process of step S315, it is possible to prevent generation of particles while a thin film is deposited on the semiconductor substrate, or a semiconductor wafer. Therefore, it is possible to improve the yield for manufacturing a semiconductor device. The thin film may be deposited on another thin film already deposited on the semiconductor substrate. That is, the semiconductor substrate may include a stack gate structure in which a plurality of thin films are deposited on the semiconductor substrate.

### MODIFICATION

In the embodiment of the present invention, as an example, Si₂Cl₆ gas, which is a chloride gas as the first material gas, and NH₃ gas as the second material gas is used. However, the combination of the first and second material gases is not limited. For example, a combination of NH₃ gas and chloride gas, such as dichloro disilane (SiH₂Cl₂), SiHCl₃ or SiCl₄ can be used. By reacting SiH₂Cl₂ gas, SiHCl₃ gas or SiCl₄ gas with NH₃ gas, as shown in Reaction formulas (7), (8) and (9), subproducts such as HCl gas, H₂ gas and the like are produced.
3SiH₂Cl₂+4NH₃→Si₃N₄+6HCl+12H₂ (7)
3SiHCl₃+4NH₃→Si₃N₄+3HCl+6H₂ (8)
3SiCl₄+4NH₃→Si₃N₄+12HCl (9)

By reacting HCl gas generated by Reaction formulas (7), (8) and (9), respectively, with NH₃ gas as the second material gas, as shown in Reaction formula (2), solid NH₄Cl is produced. The solid NH₄Cl adheres to the inner wall of the manifold 113. The solid NH₄Cl is further reacted with the first material gas, such as SiH₂Cl₂ gas, SiHCl₃ gas or SiCl₄ gas, as shown in Reaction formulas (10), (11) and (12). Consequently, subproducts such as SiHCl₃ gas, SiCl₄ gas or the like are produced and become particles.
xNH₄Cl+ySiH₂Cl₂→zSiHCl₃+wSiCl₄+xNH₃ (10)
xNH₄Cl+ySiHCl₃→zSiHCl₃+wSiCl₄+xNH₃ (11)
xNH₄Cl+ySiCl₄→zSiHCl₃+wSiCl₄+xNH₃ (12)

Here, as shown in Reaction formulas (10), (11) and (12) when the partial pressure of SiH₂Cl₂, the lower the partial pressure of SiHCl₃ or the partial pressure of SiCl₄ becomes and the higher the partial pressure of NH₃ becomes, the reaction is more suppressed. The suppression gas introduction pipe 26 introduces NH₃ gas as the suppression gas supplied from the suppression gas source 23 to the upstream side of the reaction tube 11 in the horizontal direction. Consequently, the partial pressure of NH₃ in the upstream side of the reaction tube 11 is increased, and generation of SiHCl₃ gas and SiCl₄ gas shown in Reaction formulas (10), (11) and (12) is suppressed.

Furthermore, the suppression gas introduction pipe 26 shown in FIG. 1 and the exhaust pipe 31 are displaced at a position opposite to each other, and the suppression gas flows in the horizontal direction from the suppression gas introduction pipe 26. However the suppression gas may flow to the upstream side of the reaction tube 11 so as to increase density of NH₃ gas. For example, the positions of the suppression gas introduction pipe 26 and the exhaust pipe 31, and a discharge position of the suppression gas by the suppression gas introduction pipe 26 are not limited.

Furthermore, the positions of the first and second material gases introduction pipes 24 and 25 are not limited. The first and second material gas introduction pipes 24 and 25 may be disposed at a horizontal level, the same as the suppression gas introduction pipe 26. Here, there is a case in which Si of the second material gas is deposited in the neighborhood of the second material gas introduction pipe 25 when NH₃ is deficient. To prevent deposition of Si, it is preferable to displace the suppression gas introduction pipe 26 to a lower horizontal level than the horizontal level of the second material gas introduction pipe 25.

Furthermore, the target object (substrate) 1 may be heated by infrared annealing, RF heating, or the like, instead of the heating furnace 13.

Furthermore, vapor phase reaction of the first material gas with the second material gas, or surface reaction on a surface of a substrate may be supported or excited by photo energy or plasma energy.

Various modifications will become possible for those skilled in the art after receiving the teachings of the present disclosure without departing from the scope thereof.

What is claimed is:

1. A semiconductor manufacturing system adapted for depositing a thin film on a target object, comprising:
a reaction tube configured to house the target object;
a plurality of material gas introduction pipes, connected to an upstream side of the reaction tube, configured to introduce a first material gas containing a compound of silicon, and a second material gas containing at least one of nitrogen gas and a compound of nitrogen, in the reaction tube, respectively and independently of each other; and
a suppression gas introduction pipe, connected to an upstream side of the reaction tube, configured to introduce a suppression gas to suppress generation of a reaction subproduct generated by a reaction between the first and second material gases.

2. The semiconductor manufacturing system of claim 1, wherein the suppression gas introduction pipe introduces the suppression gas in a direction different from directions in which the material gas introduction pipes introduce the first and second material gases.

3. The semiconductor manufacturing system of claim 1, wherein the material gas introduction pipes introduces the first and second material gases in a vertical direction respectively, so that the first and second material gases flow from the upstream side of the reaction tube to the downstream.

4. The semiconductor manufacturing system of claim 1, wherein the suppression gas introduction pipe introduces the suppression gas in a horizontal direction, so that the suppression gas flows to the upstream side of the reaction tube.

5. The semiconductor manufacturing system of claim 1, wherein the first material gas contains chloride gas.

6. The semiconductor manufacturing system of claim 1, wherein the second material gas contains ammonia gas.

7. The semiconductor manufacturing system of claim 1, wherein the suppression gas contains ammonia gas.

8. The semiconductor manufacturing system of claim 1, further comprising an exhaust pipe connected to the upstream side of the reaction tube.

9. The semiconductor manufacturing system of claim 8, wherein the exhaust pipe exhausts the subproduct from the reaction tube.

10. The semiconductor manufacturing system of claim 8, wherein the exhaust pipe exhausts the suppression gas from the reaction tube.

11. The semiconductor manufacturing system of claim 8, wherein the suppression gas introduction pipe and the exhaust pipe are disposed at positions opposite to each other.

12. The semiconductor manufacturing system of claim 8, further comprising an exhaust pressure adjustment tool configured to adjust an exhaust pressure of the exhaust pipe.

13. The semiconductor manufacturing system of claim 8, further comprising an analysis meter configured to analyze at least one of a composition and density of gas exhausted from the exhaust pipe.

14. The semiconductor manufacturing system of claim 13, further comprising a control circuit configured to control an amount of the suppression gas introduced from the suppression gas introduction pipe, based on an analysis result by the analysis meter.

15. The semiconductor manufacturing system of claim 1, further comprising a heating furnace disposed outside of the reaction tube and configured to control a temperature in the reaction tube.

16. The semiconductor manufacturing system of claim 1, wherein the reaction tube comprises:
an outer pipe;
an inner tube configured to house the target object disposed inside of the outer pipe; and
a manifold under the outer pipe.

17. The semiconductor manufacturing system of claim 16, wherein the manifold is connected to one end of each of the material gas introduction pipes, and one end of the suppression gas introduction pipe, respectively.

18. The semiconductor manufacturing system of claim 17, further comprising a gas supply system connected to the other end of the material gas introduction pipes, and the other end of the suppression gas introduction pipe, respectively.

19. The semiconductor manufacturing system of claim 16, further comprising an outlet pipe connected to the outer pipe.

20. A method for manufacturing a semiconductor device, comprising:
heating a semiconductor substrate in a reaction tube to a growth temperature;
maintaining the growth temperature;
introducing a first material gas containing a compound of silicon, and a second material gas containing at least one of nitrogen gas and a compound of nitrogen from an upstream side of the reaction tube, respectively and independently of each other so as to deposit a thin film on the semiconductor substrate from a reaction between the first and the second material gases; and
introducing a suppression gas, to suppress generation of a reaction subproduct generated by the reaction, from the upstream side of the reaction tube.
